(19) United States
(12) Patent Application Publication
(10) Pub. No.: US 2026/0036970 A1
(43) Pub. Date: Feb. 5, 2026

(54) METHOD OF MANUFACTURING INTEGRATED CIRCUIT (IC) DEVICE HAVING STAND-ALONE FEED-THROUGH VIA AND SYSTEM FOR SAME

(71) Applicant: TAIWAN SEMICONDUCTOR MANUFACTURING COMPANY, LTD., Hsinchu (TW)

(72) Inventors: Yueh-Ling HSU, Hsinchu (TW); Wen-Hao CHEN, Hsinchu (TW); Chun-Yao KU, Hsinchu (TW); Shi-Bin CHEN, Hsinchu (TW)

(21) Appl. No.: 18/793,291

(22) Filed: Aug. 2, 2024

(51) Int. Cl. G05B 19/418; G06F 30/392

(52) U.S. Cl. CPC G05B 19/41885; G06F 30/392; G05B 2219/45028

(57) ABSTRACT

A method of manufacturing an integrated circuit (IC) device includes: designing a circuit layout, including a selecting among a first pattern and a second pattern as possible patterns for forming a conductive structure by selecting the pattern that will undergo the least change during optical proximity correction (OPC) of the circuit layout, wherein the selecting the pattern that will undergo the least change during OPC of the circuit layout includes using a machine learning model to predict changes to the first pattern and the second pattern during OPC; and fabricating a lithographic mask that includes a third pattern, the third pattern being obtained by performing OPC on the selected pattern.

### BACKGROUND

An integrated circuit (“IC”) device or semiconductor device includes one or more devices represented in an IC layout diagram (also referred to as a “layout diagram”). A layout diagram is hierarchical and includes modules which carry out higher-level functions in accordance with the IC design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

Reducing signal delays, e.g., resistance-capacitance (RC) delays, in an integrated circuit (IC) device or semiconductor device is a design consideration. An approach to reducing signal delays involves reducing distances and/or RC characteristics of wiring connections such as routing connections.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an integrated circuit device, according to some embodiments.

FIG. 2A is a flow diagram of aspects of an integrated circuit device manufacturing process, according to some embodiments. FIGS. 2B-2D are diagrams of examples corresponding to operations in FIG. 2A.

FIG. 3 is a schematic diagram of training an incipient machine learning model, according to some embodiments.

FIG. 4 is a schematic diagram of place and route operations using a trained machine learning model, according to some embodiments.

FIGS. 5A-F are examples of marker-guided optical proximity correction, in accordance with some embodiments.

FIG. 6 is a flowchart of a method of generating a layout and using the layout to fabricate an integrated circuit device, in accordance with some embodiments.

FIG. 7 is a flowchart of a method of generating a layout, in accordance with some embodiments.

FIG. 8 is a flowchart of a method of fabricating one or more components of an integrated circuit device, based on the layout, in accordance with some embodiments.

FIG. 9 is a block diagram of an electronic design automation system in accordance with some embodiments.

FIG. 10 is a block diagram of an integrated circuit manufacturing system, and an integrated circuit manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain(s) may refer to a source or a drain, individually or collectively dependent upon the context.

In designing and fabricating an integrated circuit (IC) device, a placement and routing process (or “place and route” (PnR)) is a process whereby a circuit design or netlist for the IC device is converted to a physical or actual device layout using PnR tools that place circuit elements (e.g., logic gates, memory blocks, and the like) within a defined space or die area (placement) and then connect the circuit elements (routing). Placement includes determining physical locations of the circuit elements (which in some cases correspond to standard cells from a library of standard cells) in the layout while also considering factors such as wire length, routing congestion, timing delays, and the like. Routing includes connecting the placed circuit elements using conductors, e.g., metal wires, which may be routed on multiple metal layers, while following rules and limitations of the manufacturing process or technology node. Routing operations may be performed as one or more iterations of routing algorithms to optimize the placement of conductors, number of routing layers, and the like for factors such as timing, power, and signal integrity.

Optical proximity correction (OPC) is a photolithography enhancement technique that modifies a lithographic mask (photomask) to compensate for image errors (pattern errors) due to diffraction, process effects, or the like. OPC modifications to an intended pattern can include, among other things, moving edges and/or adding polygons to a photomask pattern such that a finally-fabricated pattern closely reproduces the intended pattern. OPC involves trade-offs and approximations that result in various pattern modification possibilities during OPC. Changes to patterns in a circuit made during OPC can degrade electrical characteristics of the fabricated device relative to the device layout that resulted from placement and routing (and prior to OPC).

According to some embodiments, PnR and OPC operations are performed using a machine learning (ML) model that combines layout information, information relating to pattern changes during OPC, and electrical data. The ML model is used in the PnR operations to perform placement and/or routing with consideration of pattern changes that may be implemented in OPC. The PnR operations use OPC-optimized patterns from the ML model for better timing and power performance. Also, according to some embodiments, OPC pattern changes are made with a focus not just on manufacturability but also with consideration of changes in electrical characteristics such as clock timing, power, and the like. The ML model is used in the OPC operation to perform OPC with consideration of how pattern changes during OPC impact electrical characteristics of the device. This effectively links the PnR and OPC operations, and improves step-to-step correlation between the PnR layout (pre-OPC) and the post-OPC layout. A lithographic mask is formed using OPC-derived patterns. An IC device formed using the ML-guided OPC exhibits improved electrical characteristics and/or electrical characteristics that are closer to a design specification in some embodiments.

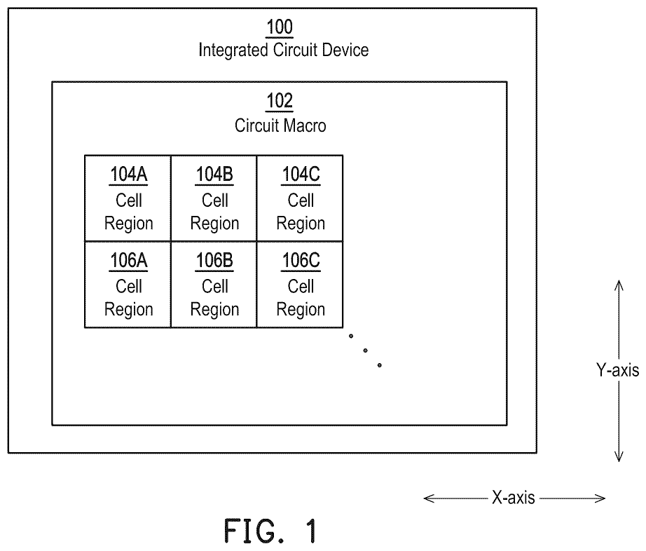

FIG. 1 is a block diagram of an integrated circuit (IC) device 100, e.g., a semiconductor device, according to some embodiments.

In FIG. 1, an IC device 100 includes, among other things, a circuit macro 102. The circuit macro 102 includes, among other things, cell regions 104A, 104B, 104C, et seq., and cell regions 106A, 106B, 106C, et seq., which operate to perform one of more function of the IC device 100. In some embodiments, the cells regions 104A . . . 106C each represent different types of circuits such as memory cells, power control circuits, inverters, latches, buffers, or the like, and/or any other type of circuit arrangement that is represented in a cell library.

The circuit macro 102 is an implementation or fabrication of a circuit design according to or at a given semiconductor process technology node. In some embodiments, the circuit macro 102 is implemented or fabricated based on a layout diagram that represents the circuit design, the layout diagram itself having been generated under the given semiconductor process technology node. In some embodiments, the layout diagram is based on a netlist that represents the circuit design, the netlist itself having been generated under the given semiconductor process technology node.

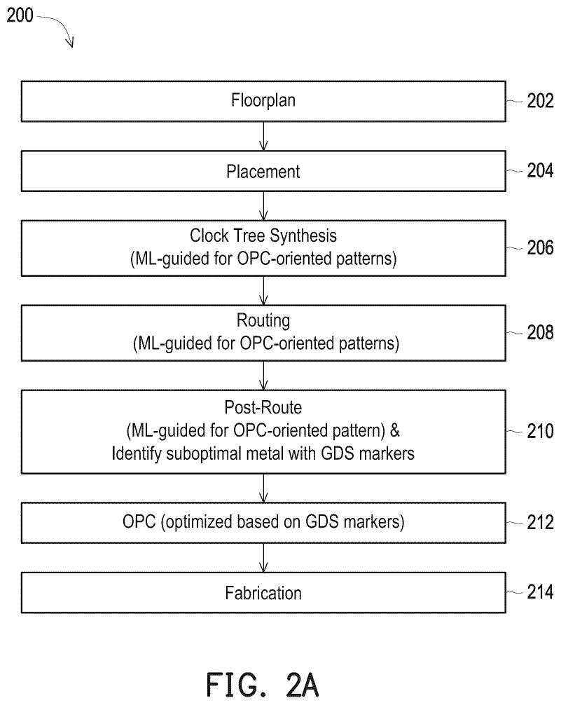

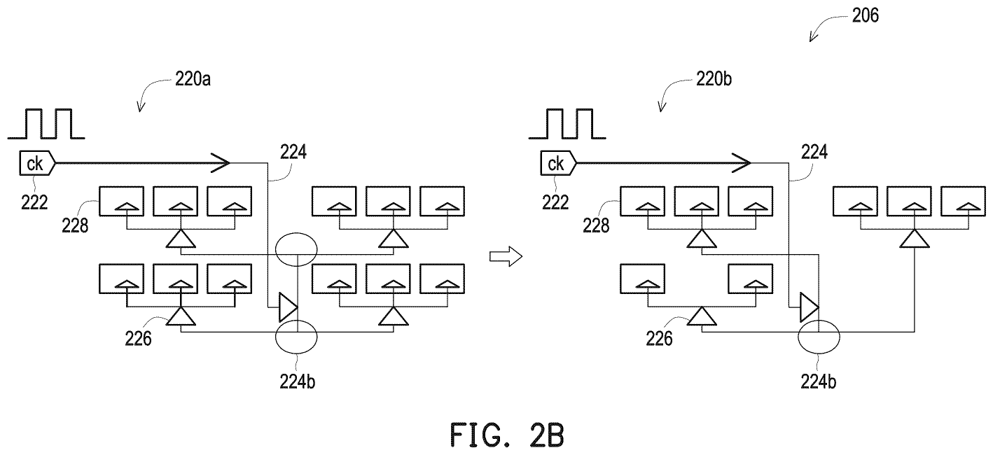

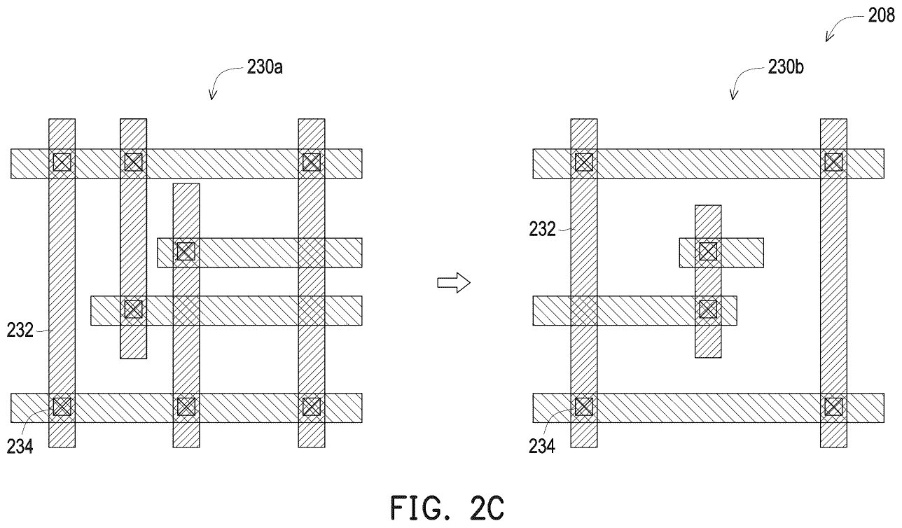

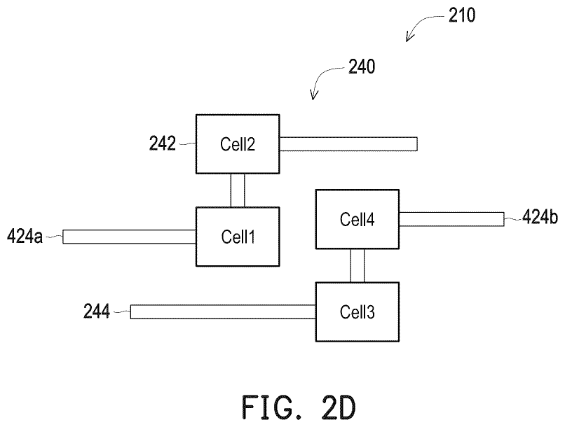

FIG. 2A is a flow diagram 200 of aspects of an IC device manufacturing process, according to some embodiments. FIGS. 2B-2D are diagrams of examples corresponding to operations 206, 208, and 210 in FIG. 2A.

In some embodiments, aspects of the flow diagram 200 are performed using an electronic design automation (EDA) system. In some embodiments, the EDA system includes an automatic placement and routing (APR) system.

In FIG. 2, the flow diagram 200 beings with a floorplan operation and a placement operation. The flow diagram 200 includes a first block 202 of generating a floorplan and a second block 204 of a placement operation to determine locations of cells. In some embodiments, the floorplan is generated as a layout diagram, e.g., a digital diagram, that represents where cells, e.g., the cells regions 104A . . . 106C, are to be placed. In some embodiments, the layout diagram is described digitally in a binary file format (e.g., a Graphic Database System (GDS) format such as a Graphic Database System II (GDSII) stream format), where the binary file format represents planar geometric shapes, text labels, other information and the like in hierarchical form. The placement operation 204 is part of a place and route (PnR) operation whereby exact locations of circuit elements are determined.

In block 206, a clock tree synthesis (CTS) operation includes clock tree design for distributing clock signals to clock pins based on physical and/or layout information. The CTS operation 206 is performed with input from machine learning (described in detail below) such that elements of the clock tree (e.g., conductive patterns or metal patterns) are selected based, at least in part, on how the patterns will be changed during optical proximity correction (OPC) at a later stage in the IC manufacturing process.

Herein, the term “design pattern” refers to a pattern in an IC design, e.g., a pattern in a layout. The term “mask pattern” refers to a pattern written to a lithography mask. The term “fabricated pattern” refers to a pattern (made using the mask pattern) in a fabricated device. In some embodiments, the fabricated pattern is a conductive structure in an IC device. The mask pattern is often not exactly the same as the design pattern, but rather is intentionally modified from the design pattern by OPC (to account for image errors due to diffraction, process effects, and the like) such that the final, fabricated pattern closely represents the design pattern. Ideally, OPC produces a mask pattern that will result in an exact match of the fabricated pattern to the design pattern. In practice, however, limitations in the OPC design process itself and/or external costs of OPC (e.g., increases in OPC time, computational workloads, mask complexity, and the like) mean that the fabricated pattern is often not an exact match to the design pattern.

In the CTS operation 206, PnR tools incorporate guidance from machine learning to generate OPC-oriented clock tree patterns (e.g., conductive patterns or metal patterns). OPC-oriented patterns are design patterns that require fewer changes (e.g., to pattern shapes, sizes, and/or placement) during OPC than non-OPC-oriented patterns. Reducing the number of changes to pattern shapes during OPC helps to minimize differences in electrical characteristics between a manufactured IC and the intended or simulated IC design, leading to improved manufacturability, higher yields, and/or higher performance integrated circuits (ICs).

In another approach, CTS does not take into account changes to patterns (such as modifying a pattern shape, extending or shrinking pattern dimensions, or displacing a pattern) that are made during the subsequent OPC operation. Thus, the subsequent OPC operation can result in the fabricated device exhibiting clock tree behaviors (e.g., clock timing, clock skew, or the like) that differ from an intended or simulated clock tree behavior. Changes to clock tree patterns during OPC can lead to, e.g., setup time or hold time failure, resistance-capacitance (RC) misalignment (differences in resistance and/or capacitance) causing data to arrive outside of an expected timing window, or the like, in a fabricated IC device.

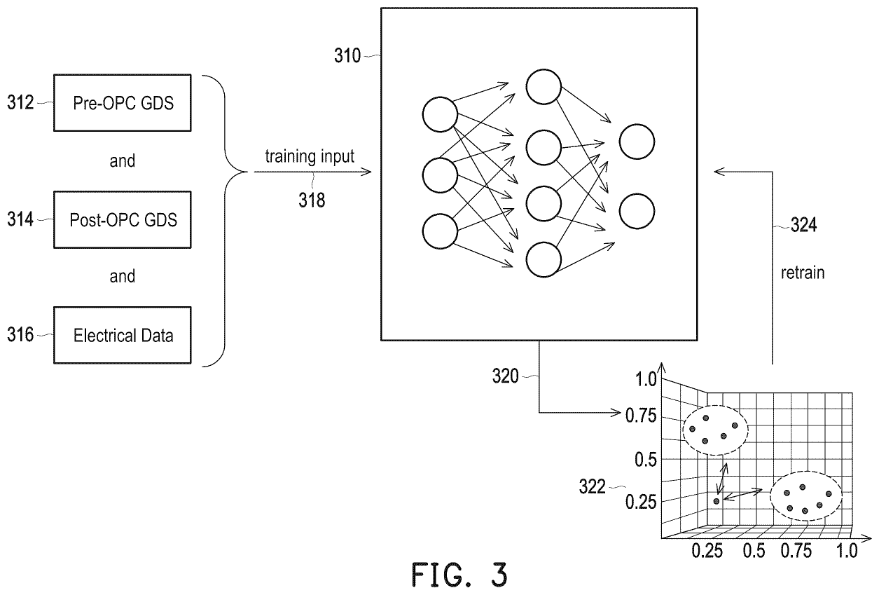

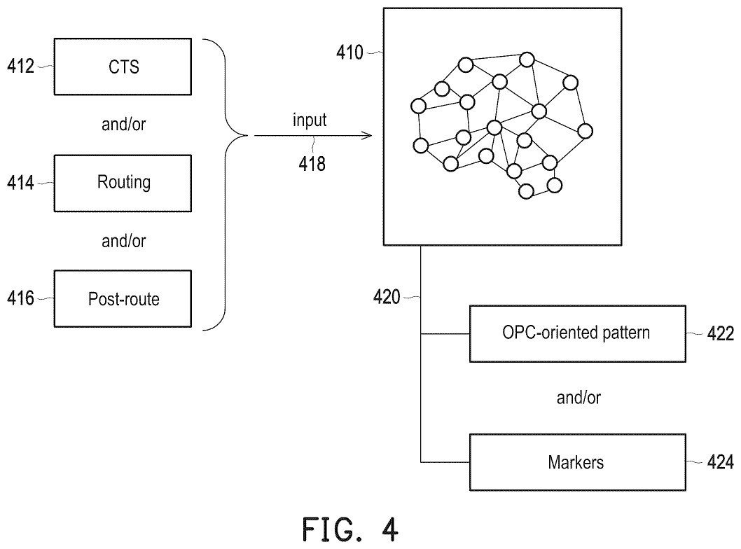

According to embodiments, the CTS operation 206 is performed using information from a machine learning (ML) model that models electrical changes (e.g., timing-related and/or power-related changes) that occur as a result of pattern changes during the OPC operation 212. As a result, the fabricated device more closely matches the intended device or design. The ML-guided CTS operation 206 will now be described in detail in connection with FIGS. 3 and 4.

FIG. 3 is a schematic diagram of training an incipient ML model 310, according to some embodiments.

In FIG. 3, an incipient or in-training ML model 310 is trained using a pre-OPC design 312, a corresponding post-OPC design 314, and corresponding electrical data 316 as training inputs 318. In some embodiments, the pre- and post-OPC designs are provided to the incipient ML model 310 in the form of GDS files. In some embodiments, the electrical data 316 includes one or more of timing data, power data, or like information. In some embodiments, the timing data includes data for at least one critical timing path, where the critical timing path is a longest delay path that limits a maximum clock frequency of a circuit. In some embodiments, the electrical data includes maximum clock frequency data for at least one critical timing path. In some embodiments, the electrical data 316 includes electrical information (e.g., timing-related or power-related information) simulated from the pre-OPC design 312 and/or the post-OPC design 314. In some embodiments, the electrical data 316 includes electrical information derived from a device fabricated using the post-OPC design 314.

The incipient ML model 310 is trained to model electrical changes (e.g., timing-related and/or power-related changes) that occur as a result of pattern changes during OPC. In some embodiments, the training of the incipient ML model 310 includes one or more cycles of using the incipient ML model 310 for inferencing (e.g., making predictions or classifications), evaluating a training output 320 of the incipient ML model 310 for correspondence or convergence 322 between input data and output data, and retraining 324 until a trained model is arrived at (see trained ML model 410 in FIG. 4). In some embodiments, the training includes inputting pre-OPC and post-OPC GDS data to the incipient ML model 310, and decomposing the input GDS data to characterize OPC behaviors for different routing patterns and/or pattern shapes, e.g., metal widths, metal spacings on one side of a substrate, metal spacings on both side of a substrate, metal shapes in different process windows, or the like. In some embodiments, the training evaluation includes classifying a database according to different categories, e.g., like OPC or unlike OPC, whereby the ML model 310 decomposes the GDS data, characterizes OPC behaviors with different routing patterns, and classifies a database into like OPC or unlike OPC categories. In some embodiments, training is directed to generating or predicting design patterns that require fewer OPC operations and/or fewer OPC changes to patterns. The training is performed so that the trained model generates or predicts patterns that are closer to a post-OPC pattern, to thus produce an IC design in which the post-OPC design (e.g., a post-OPC GDS file) exhibits an improved correlation to the intended or simulated design in terms of electrical characteristics such as timing and/or power.

FIG. 3 shows a single incipient ML model 310 being trained. In some embodiments, a single ML model is used to generate patterns for multiple PnR operations, e.g., CTS, routing, and post-route operations. In other embodiments, multiple ML models are used, e.g., a different model is trained for each PnR of CTS, routing, and post-route operations.

FIG. 4 is a schematic diagram of place and route (PnR) operations using a trained ML model 410, according to some embodiments.

In FIG. 4, the trained ML model 410 is the result of the training of the incipient ML model 310, as described above. In some embodiments, the trained ML model 410 is implemented as a neural network having a plurality of layers and optimized weights and biases.

The trained ML model 410 is used to by the PnR tools in the CTS operation 206 to generate or predict OPC-oriented patterns 422 for the clock tree design or layout. In some embodiments, the trained ML model 410 is provided with an IC layout, e.g., in the form of a GDS file, and uses inferencing to generate or predict patterns that will undergo relatively few changes during OPC, i.e., OPC-oriented patterns 422, as compared to non-OPC-oriented patterns.

In detail, CTS data 412, which may be in the form of one or more GDS file elements or layers, is input to the trained ML model 410 in the CTS operation 206. The trained ML model 410 generates an output 420 that includes or identifies one or more OPC-oriented patterns for the clock tree design or layout in the CTS operation 206. The OPC-oriented patterns 422 are patterns used in the CTS operation 206 to construct or lay out the clock tree while minimizing differences in electrical characteristics of the clock tree between the intended or simulated IC design and the fabricated device. According to some embodiments, the clock tree in the fabricated device exhibits fewer deviations or discrepancies relative to the clock tree design, due to the CTS operation 206 being performed using the OPC-oriented patterns 422. This leads to improved manufacturability, higher yields, and/or higher performance integrated circuits (ICs).

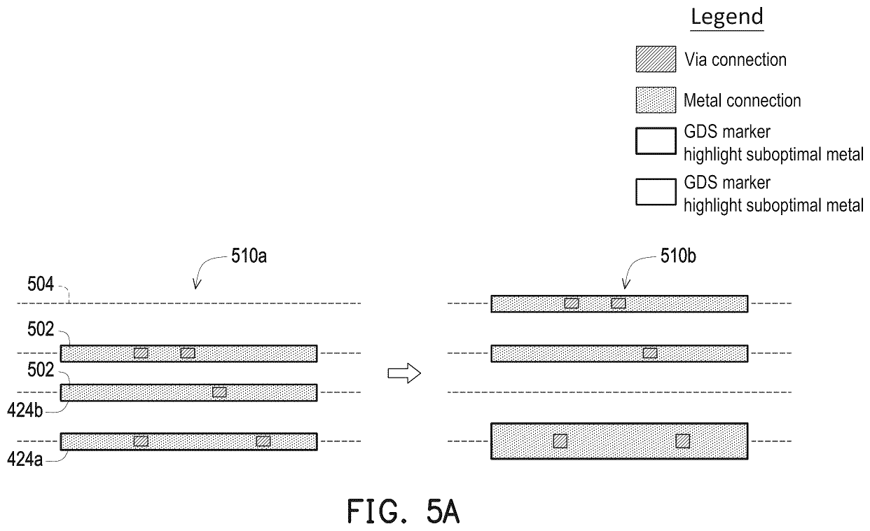

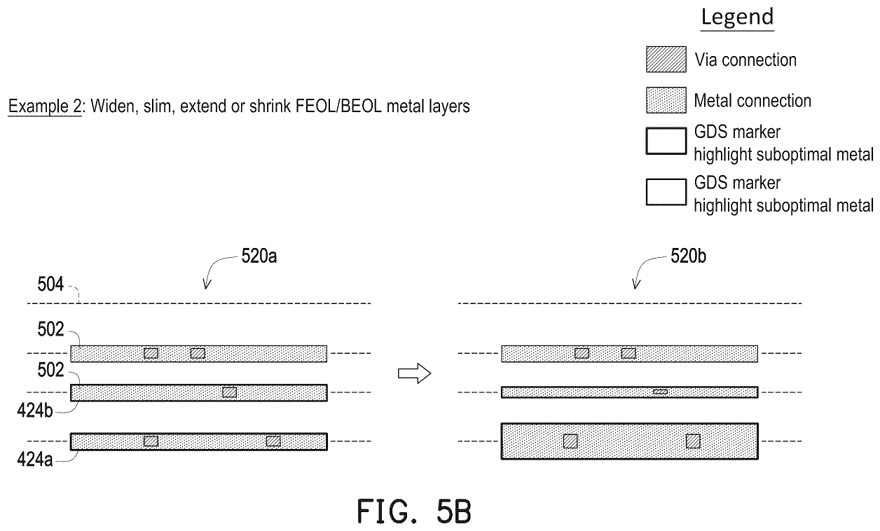

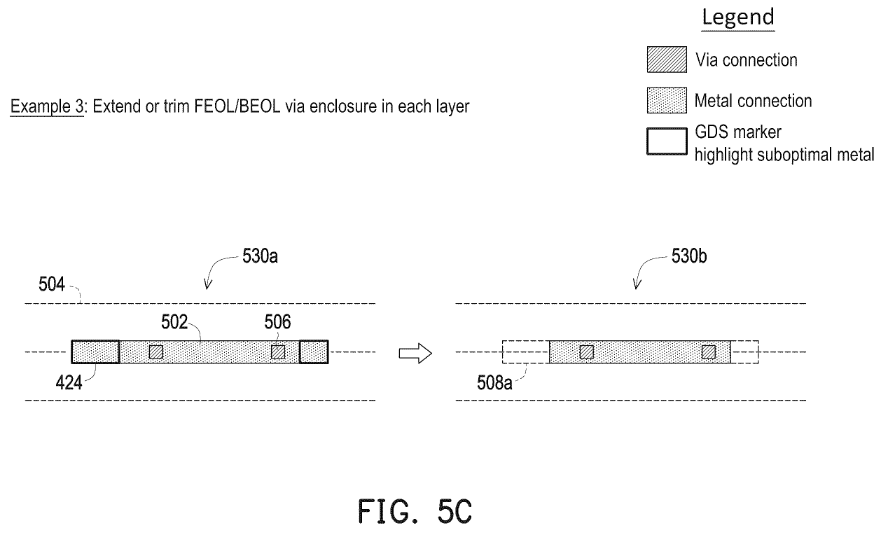

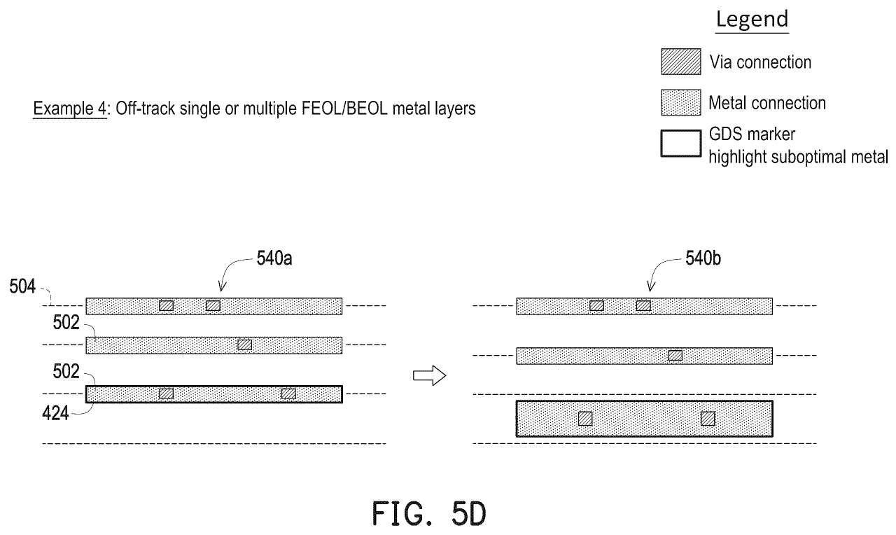

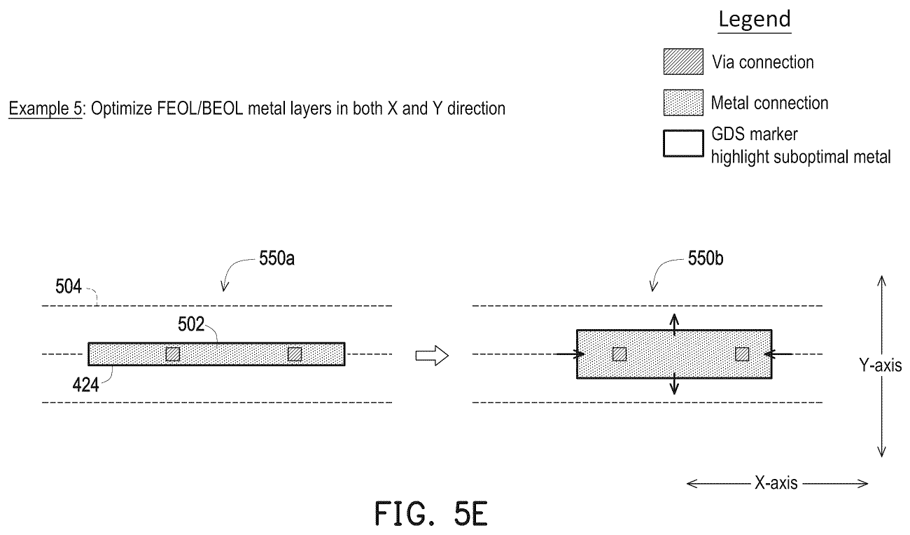

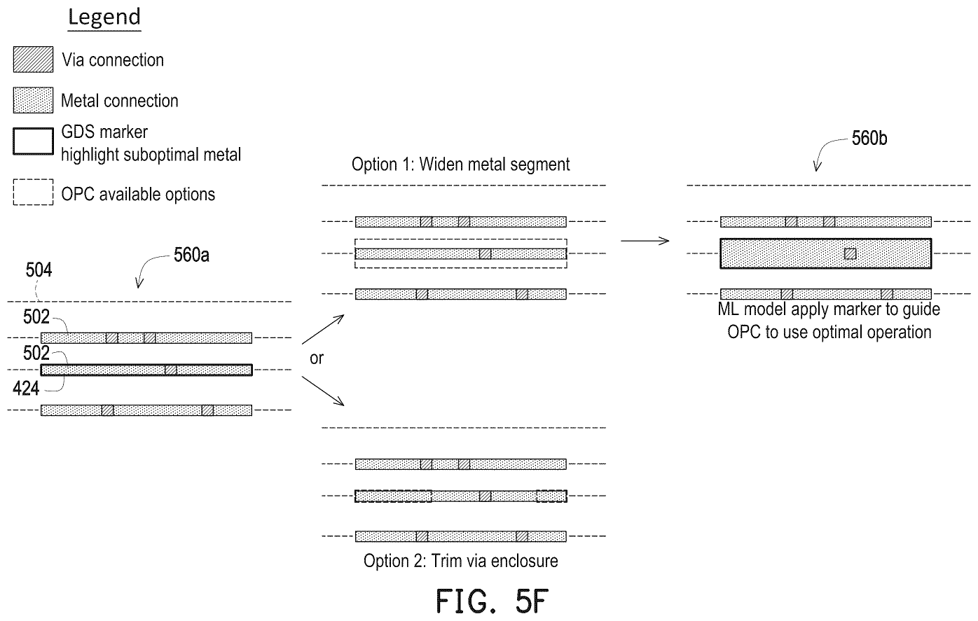

In FIG. 4, the trained ML model 410 is also used to generate markers 424. In some embodiments, the trained ML model 410 is provided with an IC layout, e.g., in the form of a GDS file, and uses inferencing to generate or predict the markers 424 to identify patterns, e.g., sub-optimal metals, for reference during OPC. The markers 424 are described in detail below in connection with FIGS. 5A-F.

An example of an ML-guided change in the CTS operation 206 of FIG. 2A is shown in FIG. 2B. In FIG. 2B, a first clock tree design 220a is modified in the CTS operation 206 to be a second clock tree design 220b that will be fabricated using one or more OPC-oriented patterns. In some embodiments, the second clock tree design 220b has a different design from the first clock tree design 220a, in order that the electrical characteristics of the clock tree (e.g., timing, skew, or the like) in the fabricated device are not substantially altered by OPC pattern changes. In the example in FIG. 2B, in the first clock tree design 220a, a clock 222 drives an oscillating clock signal ck on a clock path 224. The clock path 224 in the first clock tree design 220a includes two branches 224b, and is driven with five buffers 226 to provide the clock signal to twelve clock sinks 228, e.g., flip-flops or the like. The CTS operation 206 modifies the first clock tree design 220a to the second clock tree design 220b using the trained ML model 410 so that the clock tree in the fabricated device is less likely to deviate from the intended clock tree design (in terms of timing, skew, or the like) due to pattern changes during OPC. In the second clock tree design 220b, there are one branch 224b, four buffers 226, and eight clock sinks 228. The ML-guided PnR tools thus perform the CTS operation 206 to generate OPC-oriented CTS patterns so that the second clock tree design 220b exhibits, in the final device, electrical characteristics that are closer to the intended characteristics than would be achieved using the first clock tree design 220a.

Following the CTS operation 206, a routing operation is performed in block 208. In the routing operation 208, the PnR tools use the trained ML model 410 to generate OPC-oriented patterns for routing (e.g., conductive patterns or metal patterns for power and/or signal net routing of the cells) that require fewer changes during OPC. In the same manner as described in connection with the CTS operation 206, performing the routing operation using the trained ML model 410 reduces the number of changes to pattern shapes during OPC, and helps to minimize differences in electrical characteristics between a manufactured IC and the intended or simulated IC design, leading to improved manufacturability, higher yields, and/or higher performance ICs.

An example of an ML-guided routing operation 208 of FIG. 2A is shown in FIG. 2C. In FIG. 2C, a first routing design 230a is modified in the routing operation 208 to be a second routing design 230b that will be fabricated using one or more OPC-oriented patterns. In some embodiments, the second routing design 230b has a different design from the first routing design 230a, in order that electrical characteristics of signals and/or power that flow through the routing in the fabricated device are not substantially altered by OPC pattern changes. In the example in FIG. 2C, in the first routing design 230a, eight routing elements 232 are interconnected using eight vias 234. The routing operation 208 modifies the first routing design 230a to the second routing design 230b using the trained ML model 410 so that the signal and/or power characteristics in the fabricated device are less likely to deviate from the intended signal and/or power characteristics due to pattern changes during OPC. In the second routing design 230b, there are seven routing elements 232 and six vias 234. The ML-guided PnR tools thus perform the routing operation 208 to generate OPC-oriented routing patterns so that the second routing design 230b exhibits, in the final device, electrical characteristics that are closer to the intended characteristics than would be achieved using the first routing design 230a.

Next, a post-route and marking operation is performed in block 210. In some embodiments, the post-route operation 210 includes a timing analysis of the IC design or layout created in the preceding operations 202˜208. In the post-route operation 210, the PnR tools modify the IC design or layout based on the timing analysis and using the trained ML model 410 to generate OPC-oriented patterns for use in the timing analysis-based modifications. Again, the OPC-oriented patterns require fewer changes during OPC, which helps to minimize differences in electrical characteristics between the intended or simulated IC design and the fabricated device, leading to improved manufacturability, higher yields, and/or higher performance ICs.

The post-route operation 210 also includes using the timing analysis and the trained ML model 410 to generate markers 424 that indicate or identify sub-optimal patterns (e.g., conductive patterns or metal patterns), which are patterns that are less than optimal in terms of electrical characteristics (e.g., timing and/or power) or other PnR characteristics.

In some embodiments, the post-route operation 210 includes performing a design rule check/layout versus schematic (DRC/LVS) process. The DRC is performed to check if there are any design rule violations. The LVS is performed to check if the layout netlist of the IC matches the schematic netlist of the IC.

In some embodiments, the ML-generated markers 424 identify patterns that are less than optimal in terms of critical timing paths. In some embodiments, the ML generated markers 424 identify patterns that limit a maximum clock frequency on critical timing paths. In some embodiments, the markers 424 are generated as a layer in a GDS file.

An example of the ML-generated marking aspect of post-route and marking operation 210 of FIG. 2A is shown in FIG. 2D. In FIG. 2D, a portion of a cell layout 240 is shown. The cell layout 240 includes four cells 242 and six conductive or metal elements 244, which in some embodiments convey signals and/or power to or from the cells 242. In the example in FIG. 2D, two of the conductive elements 244 are marked, one with a first marker 424a and another with a second marker 424b. The trained ML model 410 generates the markers 424a, 424b to identify patterns that are less than optimal in terms of electrical characteristics. The ML model-generated markers 424a, 424b are used during OPC to optimize electrical characteristics of patterns, e.g., patterns that form parts of critical timing paths. In some embodiments, the markers 424a, 424b are generated as a layer in a GDS file.

Referring again to FIG. 2A, an OPC operation 212 is performed following the post-route operation 210. According to some embodiments, the markers 424 are used during the OPC operation 212 to optimize OPC pattern modification such that electrical characteristics of the fabricated device are closer to the intended design, relative to the design or layout that results from the post-route operation 210. Thus, in some embodiments the OPC operation 212 is timing-aware and/or power-aware, such that the patterns in the fabricated device are enhanced or optimized during the OPC operation 212 not only to closely reproduce the intended patterns but also to enhance the electrical characteristics of the fabricated device relative to a device made using OPC that does not account for OPC-caused electrical changes. The markers 424 can be used in at least two ways.

First, the markers 424 mark (or identify) patterns that are, at least in some cases, reshaped or moved during the OPC operation 212 to improve electrical characteristics of the fabricated device. An example of an improved electrical characteristic is a higher maximum clock frequency on a critical timing path. Thus, rather than the electrical characteristics of the design being finalized in the PnR operations of blocks 206˜210, additional pattern modifications are made during the OPC operation 212 to further improve electrical characteristics. This additional, late-stage pseudo-PnR operation allows for intentional changes to electrical characteristics beyond those established under the design rules that guide the previous PnR operations of blocks 206˜210. According to some embodiments, the markers 424 identify patterns that are changed or optimized during the OPC operation 212. In some embodiments, such changes include one or more of displacing single or multiple FEOL and/or BEOL metal layers; widening, narrowing, extending, or shrinking one or more FEOL and/or BEOL metal layers; extending or trimming FEOL and/or BEOL via enclosures in each layer; moving off-track single or multiple FEOL and/or BEOL metal layers; extending or trimming one or more FEOL and/or BEOL metal layers in X and/or Y directions, or the like. Some examples of such changes are set forth below in connection with FIGS. 5A-E.

Second, the markers 424 are used in the OPC operation 212, at least in some cases, to guide selection among OPC options, e.g., to guide selection among two or more possible post-OPC patterns, in situations where the OPC operation has multiple options available to modify a pattern. An example of such a change is set forth below in connection with FIG. 5F.

In another approach, OPC performs pattern modifications with the sole objective of producing a finally-fabricated pattern that closely matches the intended pattern in the IC layout. However, the final pattern that is fabricated based on the OPC is, in some cases, a pattern that imposes limitations on electrical characteristics such as timing, power, or the like in the fabricated device. For example, a fabricated pattern that results from OPC can exhibit resistance and/or capacitance characteristics that differ from an intended design. Further, in a case where multiple options are available during OPC for modifying a pattern, the other approach selects among the options with the sole objective of selecting a more easily manufactured pattern. However, the more easily manufactured pattern can in some cases be sufficiently different from the intended pattern that it alters electrical characteristics of the fabricated device relative to the intended design. For example, when OPC selects among multiple options, the OPC may select a pattern that is wider than an intended pattern, such that the finally-fabricated pattern exhibits lower resistance and greater capacitance than the intended pattern, causing deviations in clock, signal, and/or power that is routed through the pattern.

As described above, according to some embodiments, the OPC operation 212 uses the ML model-generated markers 424 to generate patterns or groups of patterns that result in the electrical characteristics of the fabricated device being closer to the intended electrical specification. Also, according to some other embodiments, the OPC operation 212 uses the ML model-generated markers 424 to take into account electrical considerations when selecting among multiple OPC options, rather than merely selecting an option that generates a pattern that is easier to manufacture. Examples of these two uses of the markers 424 during the OPC operation 212 will now be described.

FIGS. 5A-F are examples of marker-guided OPC, in accordance with some embodiments. In particular, FIGS. 5A-E are examples of using the ML model-generated markers 424 to mark patterns that are reshaped or moved during the OPC operation 212 to improve electrical characteristics of the fabricated device. FIG. 5F is an example of using the markers 424 to guide selections among two pattern-changing options during the OPC operation 212.

In the example in FIG. 5A, markers 424a, 424b, which are generated by the trained ML model 410, mark three metal patterns 502 in a first layout 510a. In the first layout 510a, three metal patterns 502 are set on tracks 504. One metal pattern 502 is marked with a first marker 424a and two metal patterns 502 are marked with a second marker 424b. In the OPC operation 212, the first layout 510a is modified to be a second layout 510b. In the second layout 510b, the two metal patterns 502 marked with the second markers 424b are displaced or shifted to another track 504 and the metal pattern 502 marked with the first marker 424a is made wider. In some embodiments, one or more FEOL or BEOL metal layers are displaced or shifted during the OPC operation 212. The second layout 510b exhibits, in the final device, electrical characteristics that are improved relative to what would be achieved using the first layout 510a.

In the example in FIG. 5B, markers 424a, 424b, which are generated by the trained ML model 410, mark two metal patterns 502 in a first layout 520a. In the first layout 520a, three metal patterns 502 are set on tracks 504. One metal pattern 502 is marked with a first marker 424a and one metal pattern 502 is marked with a second marker 424b. In the OPC operation 212, the first layout 520a is modified to be a second layout 520b. In the second layout 520b, the metal pattern 502 marked with the second marker 424b is made thinner and the metal pattern 502 marked with the first marker 424a is made wider. In some embodiments, one or more FEOL or BEOL metal layers are widened, made narrower, extended, or shrunk during the OPC operation 212. The second layout 520b exhibits, in the final device, electrical characteristics that are improved relative to what would be achieved using the first layout 520a.

In the example in FIG. 5C, markers 424, which are generated by the trained ML model 410, mark two ends of a metal pattern 502 in a first layout 530a. In the first layout 530a, two vias 506 connect to the metal pattern 502. Ends of the metal pattern 502 that extend beyond the vias 506 are marked with the markers 424. In the OPC operation 212, the first layout 530a is modified to be a second layout 530b. In the second layout 530b, the ends of the metal pattern 502 marked with the markers 424 are trimmed. In some embodiments, one or more FEOL or BEOL metal layers are extended or trimmed during the OPC operation 212. The second layout 530b exhibits, in the final device, electrical characteristics that are improved relative to what would be achieved using the first layout 530a.

In the example in FIG. 5D, marker 424, which is generated by the trained ML model 410, marks one of three metal patterns 502 in a first layout 540a. In the first layout 540a, the three metal patterns are each aligned with a track 504. In the OPC operation 212, the first layout 540a is modified to be a second layout 540b. In the second layout 540b, the metal pattern 502 marked with the marker 424 is displaced or shifted to be located in an off-track position, i.e., to not be aligned with a track 504, and is made wider. In some embodiments, one or more FEOL or BEOL metal layers are displaced or shifted to be in an off-track position during the OPC operation 212. The second layout 540b exhibits, in the final device, electrical characteristics that are improved relative to what would be achieved using the first layout 540a.

In the example in FIG. 5E, marker 424, which is generated by the trained ML model 410, marks metal pattern 502 in a first layout 550a. In the OPC operation 212, the first layout 550a is modified to be a second layout 550b. In the second layout 550b, the metal pattern 502 marked with the marker 424 is made shorter in the X-axis direction and is made wider in the Y-axis direction. In some embodiments, one or more FEOL or BEOL metal layers are made shorter, longer, wider, or narrower in the X-and/or Y-axis directions during the OPC operation 212. The second layout 550b exhibits, in the final device, electrical characteristics that are improved relative to what would be achieved using the first layout 550a.

In the example of FIG. 5F, marker 424 is used to guide selections among two pattern-changing options that can potentially be made during the OPC operation 212. The marker 424, which is generated by the trained ML model 410, marks one of three metal patterns 502 in a first layout 560a and determines the pattern-changing option to be made to the marked metal pattern during the OPC operation 212. In this example, there are two potential options available for modifying the metal pattern 502 during OPC. A first option is to widen the metal pattern 502 during OPC. A second option is to trim a via enclosure of the metal pattern 502 during OPC. In another approach, deciding among such options is made solely on the basis of manufacturability, i.e., the OPC operation in the other approach chooses the option that results in a pattern that is easiest to fabricate. According to some embodiments, deciding among such options is made not only on the basis of manufacturability but also using guidance from the trained ML model 410 (in the form of the marker 424). The ML model 410 only marks the more optimal option so that the OPC operation 212 only sees the more optimal option. In the example of FIG. 5F, the ML-guided OPC operation 212 is directed to the first option, to widen the metal pattern 502, on the basis of manufacturability and guidance from the trained ML model 410. Thus, in the second layout 560b, the metal pattern 502 marked with the marker 424 is made wider relative to the first layout 560a. The second layout 560b exhibits, in the final device, electrical characteristics that are improved relative to what would be achieved using the first layout 560a as modified by the second option.

As described above, the flow diagram 200 includes ML-guided operations in connection with PnR of the clock tree synthesis, route, and post-route operations. In other embodiments, the ML-guided operations are used in only one or two of the clock tree synthesis, route, and post-route operations. Likewise, FIG. 3 shows a single incipient ML model 310 being trained. In some embodiments, a single ML model is used to generate patterns for multiple PnR operations, e.g., CTS, routing, and post-routing operations. In other embodiments, multiple ML models are used, e.g., a different model is trained for each PnR operation of CTS, routing, and post-routing. Likewise, FIG. 4 shows a single trained ML model 410 being used to generate patterns. In some embodiments, a single ML model is used to generate patterns for multiple PnR operations, e.g., CTS, routing, and post-routing operations. In other embodiments, multiple ML models are used, e.g., a different model is trained for each PnR operation of CTS, routing, and post-routing.

In FIG. 2, the flow diagram 200 is completed with a fabrication operation 214 for fabricating an IC device. The fabrication operation 214 includes using a lithographic mask to form patterns one or more layers of the IC device. The lithographic mask includes OPC patterns that are selected or generated using inferences or predictions from the trained ML model 410 in OPC operation 212.

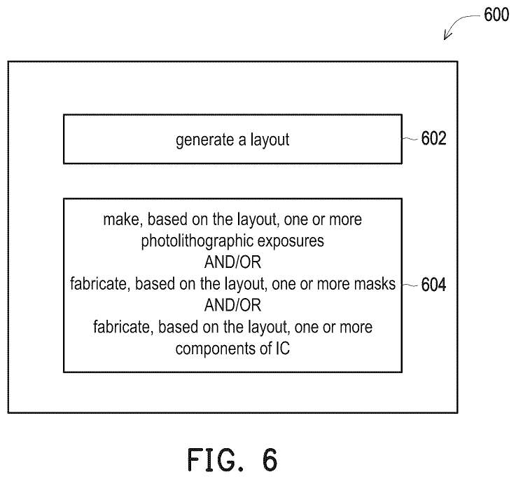

FIG. 6 is a flowchart of a method 600 of generating a layout and using the layout to fabricate an IC device, in accordance with some embodiments.

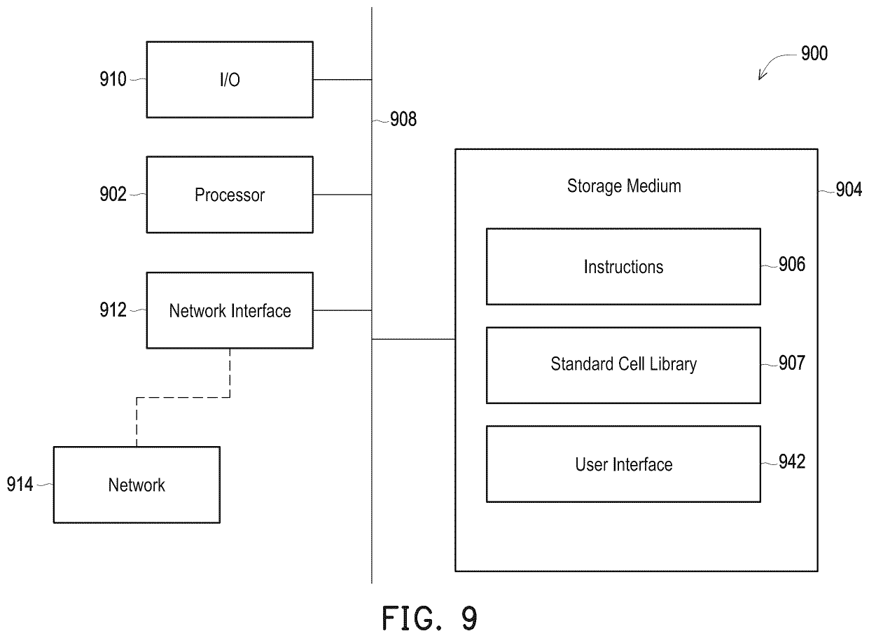

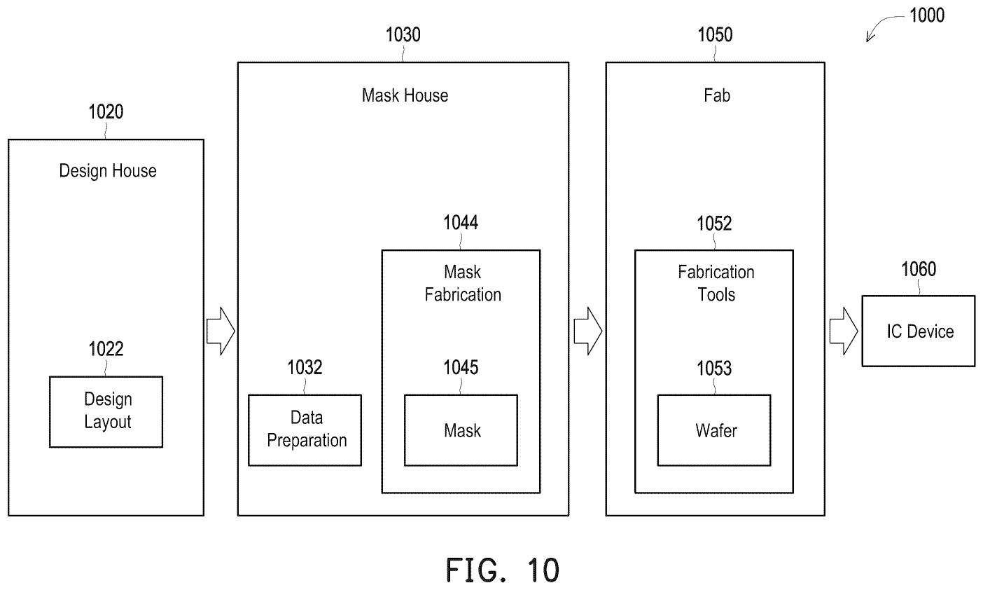

Method 600 is implementable, for example, using an electronic design automation system (see EDA system 900 in FIG. 9, discussed below) and an integrated circuit (IC) manufacturing system 1000 (FIG. 10, discussed below), in accordance with some embodiments. Regarding method 600, examples of the layout include the layouts disclosed herein, or the like. Examples of an IC device to be manufactured according to method 600 include the IC devices disclosed herein. In FIG. 6, method 600 includes operations 602, 604.

At operation 602, a layout is generated. In some embodiments, operation 602 for generating a layout includes selecting one or more standard cells from among a library of standard cells to represent a circuit macro, e.g., the circuit macro 102. In some embodiments, operation 602 includes one or more PnR operations described above, e.g., one or more of operations 204˜210. In some embodiments, operation 602 includes OPC, e.g., OPC operation 212. From operation 602, flow proceeds to operation 604.

At operation 604, based on the layout, at least one of (A) one or more photolithographic exposures are made or (B) one or more semiconductor masks are fabricated or (C) one or more components in a layer of an IC device are fabricated.

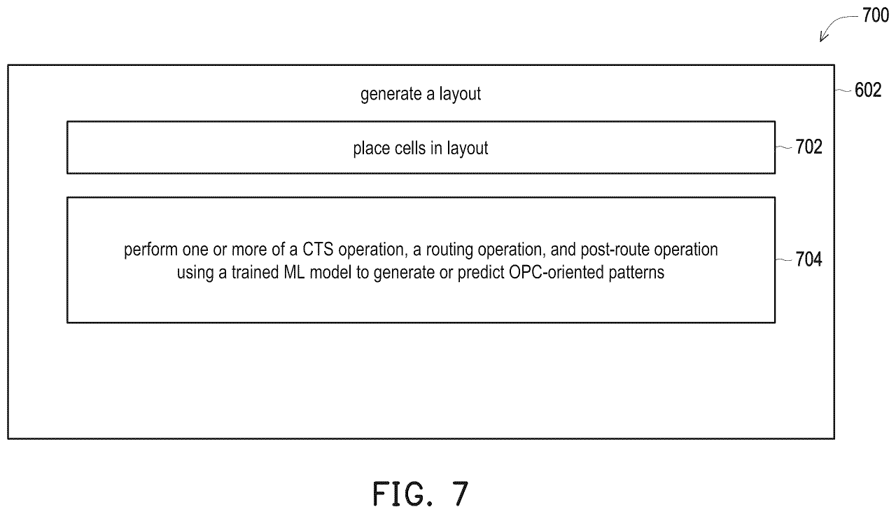

FIG. 7 is a flowchart of a method 700 of generating a layout, in accordance with some embodiments. More particularly, the flowchart of FIG. 7 shows additional operations that demonstrate one example of procedures implementable in operation 602 of FIG. 6, in accordance with one or more embodiments. In FIG. 7, operation 602 includes operations 702˜704.

At operation 702, the method includes placing cells in layout. In some embodiments, the cells represent a circuit macro, e.g., the circuit macro 102. In some embodiments, operation 702 includes placement operation 204.

At operation 704, the method includes performing one or more of a CTS operation, a routing operation, and post-route operation using a trained ML model to generate or predict OPC-oriented patterns, which are patterns that require less OPC and thus improve step-to-step correlation between pre- and post-OPC layouts while reducing OPC processing overhead and mask complexity. In some embodiments, operation 704 includes one or more of operations 206˜210. In some embodiments, operation 704 uses the trained ML model 410 to generate or predict OPC-oriented patterns.

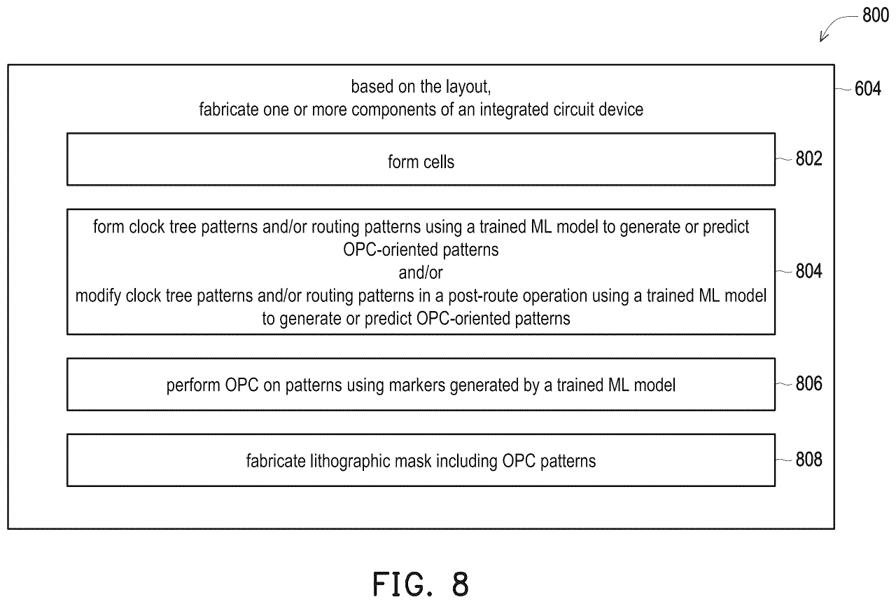

FIG. 8 is a flowchart of a method 800 of fabricating one or more components of an IC device, based on the layout, in accordance with some embodiments.

More particularly, the flowchart of FIG. 8 shows additional operations that demonstrate one example of procedures implementable in operation 604 of FIG. 6, in accordance with one or more embodiments. In FIG. 8, operation 604 includes operations 802˜808.

At operation 802, cells are formed. In some embodiments, the cells represent a circuit macro, e.g., the circuit macro 102.

At operation 804, one or more operations are performed to form clock tree patterns and/or routing patterns using a trained ML model to generate or predict OPC-oriented patterns, and/or to modify clock tree patterns and/or routing patterns in a post-route operation using a trained ML model to generate or predict OPC-oriented patterns.

At operation 806, OPC is performed on patterns, using markers generated by a trained ML model, whereby at least some of the patterns are changed in shape and/or location in order to improve electrical characteristics of the IC device. In some embodiments, the markers are the markers 424 and the trained ML model is the trained ML model 410. In some embodiments, performing OPC includes selecting among multiple OPC options using the markers.

At operation 808 a lithographic mask is fabricated. The lithographic mask includes OPC patterns that are selected or generated using inferences or predictions from the trained ML model. The lithographic mask is used to fabricate one or more layers of the IC device.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

FIG. 9 is a block diagram of an electronic design automation (EDA) system 900 in accordance with some embodiments.

In some embodiments, EDA system 900 includes an APR system. Methods described herein of designing layouts represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable storage medium 904. The computer-readable storage medium 904, amongst other things, is encoded with, i.e., stores, computer program code 906, i.e., a set of executable instructions. Execution of instructions 906 by the processor 902 represents (at least in part) an EDA tool which implements a portion or all of the methods described herein in accordance with one or more embodiments (hereinafter, the noted processes and/or methods).

The processor 902 is electrically coupled to the computer-readable storage medium 904 via a bus 908. The processor 902 is also electrically coupled to an I/O interface 910 by the bus 908. A network interface 912 is also electrically connected to processor 902 via the bus 908. Network interface 912 is connected to a network 914, so that the processor 902 and the computer-readable storage medium 904 are capable of connecting to external elements via network 914. Processor 902 is configured to execute computer program code 906 encoded in the computer-readable storage medium 904 in order to cause EDA system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, the computer-readable storage medium 904 is an electronic, magnetic, optical, electromagnetic, infrared, and/or a semiconductor system (or apparatus or device). Examples of the computer-readable storage medium 904 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 904 includes a compact disk-read only memory (CD-ROM), a compact disk-read/write (CD-R/W), and/or a digital video disc (DVD).

In one or more embodiments, the computer-readable storage medium 904 stores computer program code 906 configured to cause EDA system 900 (where such execution represents (at least in part) the EDA tool) to be usable for performing a portion or all of the noted processes and/or methods. In one or more embodiments, the computer-readable storage medium 904 also stores information which facilitates performing a portion or all of the noted processes and/or methods. In one or more embodiments, the computer-readable storage medium 904 stores library 907 of standard cells including such standard cells as disclosed herein.

The EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

The EDA system 900 also includes network interface 912 coupled to processor 902. Network interface 912 allows EDA system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 900.

The EDA system 900 is configured to receive information through I/O interface 910. The information received through I/O interface 910 includes one or more of instructions, data, design rules, libraries of standard cells, and/or other parameters for processing by processor 902. The information is transferred to processor 902 via the bus 908. EDA system 900 is configured to receive information related to a user interface (UI) through I/O interface 910. The information is stored in the computer-readable storage medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of an IC manufacturing system 1000, and an IC manufacturing flow associated therewith, in accordance with some embodiments.

In some embodiments, based on a layout, at least one of (A) one or more lithographic masks or (B) at least one component in a layer of an IC device is fabricated using the IC manufacturing system 1000.

In FIG. 10, the IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in the IC manufacturing system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1020, the mask house 1030, and the IC fab 1050 are owned by a single larger company. In some embodiments, two or more of the design house 1020, the mask house 1030, and the IC fab 1050 coexist in a common facility and use common resources.

The design house (or design team) 1020 generates an IC design layout 1022. The IC design layout 1022 includes various geometrical patterns designed for an IC device 1060. The geometrical patterns correspond to patterns of metal, oxide, or semiconductor layers that make up the various components of the IC device 1060 to be fabricated. The various layers combine to form various IC features. For example, a portion of the IC design layout 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 1020 implements a formal design procedure to form the IC design layout 1022. The design procedure includes one or more of logic design, physical design or place-and-route operation. The IC design layout 1022 is presented in one or more data files having information of the geometrical patterns. For example, the IC design layout 1022 can be expressed in a GDSII file format or DFII file format.

The mask house 1030 includes mask data preparation 1032 and mask fabrication 1044. The mask house 1030 uses the IC design layout 1022 to manufacture one or more lithography masks 1045 to be used for fabricating the various layers of the IC device 1060 according to the IC design layout 1022. The mask house 1030 performs the mask data preparation 1032, where the IC design layout 1022 is translated into a representative data file (“RDF”). The mask data preparation 1032 provides the RDF to the mask fabrication 1044. The mask fabrication 1044 includes a mask writer. The mask writer converts the RDF to an image on a substrate, such as a mask (reticle) 1045 or a semiconductor wafer 1053. The IC design layout 1022 is manipulated by the mask data preparation 1032 to comply with particular characteristics of the mask writer and/or requirements of the IC fab 1050. In FIG. 10, the mask data preparation 1032 and the mask fabrication 1044 are illustrated as separate elements. In some embodiments, the mask data preparation 1032 and the mask fabrication 1044 can be collectively referred to as mask data preparation.

In some embodiments, the mask data preparation 1032 includes ML-guided optical proximity correction (OPC) that uses lithography enhancement techniques to compensate for image errors, such as those that can arise from diffraction, interference, other process effects and the like. The OPC adjusts the IC design layout 1022. In some embodiments, the mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1032 includes a mask rule checker (MRC) that checks the IC design layout 1022 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 1022 to compensate for limitations during the mask fabrication 1044, which may undo part of the modifications performed by OPC in order to meet mask creation rules.

In some embodiments, the mask data preparation 1032 includes lithography process checking (LPC) that simulates processing that will be implemented by the IC fab 1050 to fabricate the IC device 1060. The LPC simulates this processing based on the IC design layout 1022 to create a simulated manufactured device, such as the IC device 1060. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 1022.

It should be understood that the above description of the mask data preparation 1032 has been simplified for the purposes of clarity. In some embodiments, the mask data preparation 1032 includes additional features such as a logic operation (LOP) to modify the IC design layout 1022 according to manufacturing rules. Additionally, the processes applied to the IC design layout 1022 during the mask data preparation 1032 may be executed in a variety of different orders.

After the mask data preparation 1032 and during the mask fabrication 1044, a mask 1045 or a group of masks 1045 are fabricated based on the modified IC design layout 1022. In some embodiments, the mask fabrication 1044 includes performing one or more lithographic exposures based on the IC design layout 1022. In some embodiments, an electron-beam (e-beam) or a mechanism of multiple e-beams is used to form a pattern on a mask (photomask or reticle) 1045 based on the modified IC design layout 1022. The mask 1045 can be formed in various technologies. In some embodiments, the mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1045 includes a transparent substrate (e.g., fused quartz) and an opaque material (e.g., chromium) coated in the opaque regions of the binary mask. In another example, the mask 1045 is formed using a phase shift technology. In a phase shift mask (PSM) version of the mask 1045, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1044 is used in a variety of processes. For example, such a mask(s) is used in an ion implantation process to form various doped regions in a semiconductor wafer 1053, in an etching process to form various etching regions in the semiconductor wafer 1053, and/or in other suitable processes.

The IC fab 1050 is an IC fabrication business that includes one or more manufacturing facilities for the fabrication of a variety of different IC products. In some embodiments, the IC fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1050 includes fabrication tools 1052 configured to execute various manufacturing operations on semiconductor wafer 1053 such that the IC device 1060 is fabricated in accordance with the mask(s), e.g., the mask 1045. In various embodiments, the fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1050 uses the mask(s) 1045 fabricated by the mask house 1030 to fabricate the IC device 1060. Thus, the IC fab 1050 at least indirectly uses the IC design layout 1022 to fabricate the IC device 1060. In some embodiments, the semiconductor wafer 1053 is fabricated by the IC fab 1050 using the mask(s) 1045 to form the IC device 1060. In some embodiments, the IC fabrication includes performing one or more lithographic exposures based at least indirectly on the IC design layout 1022. The semiconductor wafer 1053 includes a silicon substrate or other proper substrate having material layers formed thereon. The semiconductor wafer 1053 further includes one or more of various doped regions, dielectric features, multilevel interconnects, and the like (formed at subsequent manufacturing steps).

Details regarding an integrated circuit (IC) manufacturing system (e.g., the IC manufacturing system 1000 of FIG. 10), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

According to some embodiments, a method of manufacturing an integrated circuit (IC) device includes: designing a circuit layout, including selecting among a first pattern and a second pattern as possible patterns for forming a conductive structure by selecting the pattern that will undergo the least change during optical proximity correction (OPC) of the circuit layout, wherein the selecting the pattern that will undergo the least change during OPC of the circuit layout includes using a machine learning model to predict changes to the first pattern and the second pattern during OPC; and fabricating a lithographic mask that includes a third pattern, the third pattern being obtained by performing OPC on the selected pattern.

According to some embodiments, a method of manufacturing an integrated circuit (IC) device includes designing a circuit layout, including using a machine learning model to identify a first pattern for forming a conductive structure based on a prediction by the machine learning model that the first pattern will undergo a predetermined amount of change during optical proximity correction (OPC) of the circuit layout; and fabricating a lithographic mask that includes a second pattern, the second pattern being obtained by performing OPC on the first pattern.

According to some embodiments, a system for manufacturing an integrated circuit (IC) device includes a processor; a database coupled to the processor, the database being stored in at least one computer-readable storage medium and including graphic data system (GDS) data of a circuit layout; a machine learning model configured to generate a marker for a first pattern in a circuit layout, the marker indicating that the first pattern forms at least part of a first timing path in the circuit layout; a mask data preparer configured to perform an optical proximity correction (OPC) operation on the first pattern, based on the marker, to form a second pattern having at least one of a different shape or a different location in the circuit layout relative to the first pattern, such that a circuit including the second pattern in the first timing path exhibits a higher maximum clock frequency on the first timing path relative to the first timing path including the first pattern; and a mask writer configured to fabricate a lithographic mask that includes the second pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit (IC) device, the method comprising:
designing a circuit layout, including:
selecting among a first pattern and a second pattern as possible patterns for forming a conductive structure by selecting the pattern that will undergo the least change during optical proximity correction (OPC) of the circuit layout,
wherein the selecting the pattern that will undergo the least change during OPC of the circuit layout includes using a machine learning model to predict changes to the first pattern and the second pattern during OPC; and
fabricating a lithographic mask that includes a third pattern, the third pattern being obtained by performing OPC on the selected pattern.

2. The method of claim 1, further comprising:
forming at least one layer of the IC device using the lithographic mask.

3. The method of claim 2, wherein:
forming the at least one layer includes forming a fourth pattern based on the third pattern and corresponding to the selected pattern.

4. The method of claim 3, wherein:
the fourth pattern is formed as a conductive pattern.

5. The method of claim 3, wherein:
the fourth pattern is formed as a metal pattern.

6. The method of claim 1, wherein the first pattern is selected when the first pattern minimizes a resistance-capacitance (RC) delay in the circuit layout, relative to the second pattern.

7. The method of claim 1, wherein:
the machine learning model is trained using data of a pre-OPC circuit layout, data of a post-OPC circuit layout, and electrical data.

8. The method of claim 7, wherein:
wherein the electrical data includes data for at least one critical timing path, the critical timing path being a longest delay path that limits a maximum clock frequency of a circuit.

9. The method of claim 1, wherein:
the selected pattern is selected in one or more of a clock tree synthesis operation, a routing operation, or a post-route operation.

10. The method of claim 1, further comprising:
generating a marker using a machine learning model, the marker being applied to a fourth pattern and indicating that the fourth pattern corresponds to a sub-optimal conductive pattern in the circuit layout; and
modifying the sub-optimal conductive pattern during OPC to improve an electrical characteristic of the sub-optimal conductive pattern.

11. The method of claim 1, further comprising:
generating a marker using a machine learning model, the marker being applied to a fourth pattern and indicating that the fourth pattern corresponds to a conductive pattern in a critical timing path of the circuit layout.

12. The method of claim 11, wherein:
the marker is generated in a layer in a graphic design system data file.

13. A method of manufacturing an integrated circuit (IC) device, the method comprising:
designing a circuit layout, including using a machine learning model to identify a first pattern for forming a conductive structure based on a prediction by the machine learning model that the first pattern will undergo a predetermined amount of change during optical proximity correction (OPC) of the circuit layout; and
fabricating a lithographic mask that includes a second pattern, the second pattern being obtained by performing OPC on the first pattern.

14. The method of claim 13, wherein:
the machine learning model is trained using data of a pre-OPC circuit layout, data of a post-OPC circuit layout, and electrical data.

15. The method of claim 13, wherein:
the first pattern is used in a layout in a one or more of clock tree synthesis operation, a routing operation, or a post-route operation.

16. The method of claim 13, further comprising:
forming at least one layer of the IC device using the lithographic mask, the forming the at least one layer including forming a third pattern based on the second pattern.

17. A system for manufacturing an integrated circuit (IC) device, the system comprising:
a processor;
a database coupled to the processor, the database being stored in at least one computer-readable storage medium and including graphic data system (GDS) data of a circuit layout;
a machine learning model configured to generate a marker for a first pattern in the circuit layout, the marker indicating that the first pattern forms at least part of a first timing path in the circuit layout;
a mask data preparer configured to perform an optical proximity correction (OPC) operation on the first pattern, based on the marker, to form a second pattern having at least one of a different shape or a different location in the circuit layout relative to the first pattern, such that a circuit including the second pattern in the first timing path exhibits a higher maximum clock frequency on the first timing path relative to the first timing path including the first pattern; and
a mask writer configured to fabricate a lithographic mask that includes the second pattern.

18. The system of claim 17, wherein:
the processor is configured to provide the GDS data from the database to the machine learning model, and
the machine learning model is configured to decompose the GDS data and characterize OPC behavior for the first pattern.

19. The system of claim 17, wherein:
the first timing path is a critical timing path, the critical timing path being a longest delay path that limits a maximum clock frequency of a circuit, and
the machine learning model is a trained machine learning model that has been trained using data of a pre-OPC circuit layout, data of a post-OPC circuit layout, and electrical data that includes clock frequency data for the critical timing path.

20. The system of claim 17, wherein:
the machine learning model is configured use the marker to identify a first OPC operation from among two or more OPC operation options for the first pattern, and
the mask data preparer is configured to perform the first OPC operation based on the marker.
